(19) United States
(12) Patent Application Publication
(10) Pub. No.: US 2013/0169066 A1
(43) Pub. Date: Jul. 4, 2013

(54) ELECTRONIC DEVICE

(71) Applicants: Chia-Lung Chen, Tainan City (TW); Chuan-Che Lee, Tainan City (TW)

(72) Inventors: Chia-Lung Chen, Tainan City (TW); Chuan-Che Lee, Tainan City (TW)

(73) Assignee: HIMAX TECHNOLOGIES LIMITED, Tainan City (TW)

(21) Appl. No.: 13/343,222

(22) Filed: Jan. 4, 2012

(51) Int. Cl. H03K 17/00

(52) U.S. Cl. 307/116

(57) ABSTRACT

An electronic device has a first terminal and a second terminal and includes a control unit, a silicon controlled rectifier (SCR), and a switch unit. The control unit detects a positive pulse signal from the first terminal of the electronic device. When the positive pulse signal is detected by the control unit, the control unit generates a reset pulse after a predetermined time. The SCR has a first anode terminal, a second anode terminal, a first cathode terminal, and a second cathode terminal. The switch unit provides a plurality of transmission paths. When the switch unit receives the reset pulse, the switch unit cuts off the transmission paths, so that the first anode terminal, the second anode terminal, the first cathode terminal, and the second cathode terminal of the SCR are floating.

### BACKGROUND OF THE INVENTION

1. Field of the Invention

The invention relates to an electronic device, and more particularly to an electronic device having a silicon controlled rectifier (SCR).

2. Description of Related Art

Electrostatic discharge (ESD) often leads to electrostatic overstress or permanent damages to an integrated circuit (IC). Hence, electronic devices with ESD protection ability are extensively applied in various ICs. These types of electronic devices are often equipped with silicon controlled rectifiers (SCR) and employ the fast turn-on properties of the SCRs to achieve the ESD protection ability.

Due to the inherent limitation, the electronic device having the SCR is frequently affected by a latch-up effect, and thus the ESD protection ability of the electronic device is reduced. For instance, when an electronic device triggers the internal SCR in response to an electrostatic signal, the SCR is switched to a negative resistance region and further provides a conducting path to guide a large amount of electrostatic current. However, if the SCR is latched in the negative resistance region, the SCR cannot be switched back to the normal cutoff region. At this time, the SCR is unable to cut off the conducting path provided by the SCR itself in a normal manner, and therefore the electronic device loses the ESD protection ability.

According to the related art, a plurality of SCRs are cascaded with each other to raise a holding voltage of the SCRs and further prevent the SCRs from being latched. However, said solution results in an increase in the layout area and costs of the electronic device.

### SUMMARY OF THE INVENTION

The invention is directed to an electronic device in which a switch unit is employed, so that a silicon controlled rectifier (SCR) in the electronic device is floating. Thereby, it is not necessary to stack the SCRs together, thus preventing the SCRs from being latched and further reducing the layout area and costs of the electronic device.

In the invention, an electronic device having a first terminal and a second terminal is provided. The electronic device includes a control unit, an SCR, and a switch unit. The control unit detects a positive pulse signal from the first terminal of the electronic device. When the control unit detects the positive pulse signal, the control unit generates a reset pulse after a predetermined time. The SCR has a first anode terminal, a second anode terminal, a first cathode terminal, and a second cathode terminal. The switch unit is electrically connected to the first terminal and the second terminal of the electronic device and the silicon controlled rectifier, and provides a plurality of transmission paths. When the switch unit receives the reset pulse, the switch unit cuts off the transmission paths, so that the first anode terminal, the second anode terminal, the first cathode terminal, and the second cathode terminal of the SCR are floating.

According to an embodiment of the invention, when the switch unit does not receive the reset pulse, the switch unit turns on the transmission paths, such that the first and second anode terminals and the first terminal of the electronic device are conducted, and that the first and second cathode terminals and the second terminal of the electronic device are conducted.

According to an embodiment of the invention, the control unit includes a detector and a delayer. The detector is capable of detecting the positive pulse signal. When the positive pulse signal is detected, the detector generates a detection pulse. The delayer receives the detection pulse. After the detection pulse is delayed for the predetermined time, the delayer outputs the delayed detection pulse to serve as the reset pulse.

According to an embodiment of the invention, the detector includes a first resistor, a first capacitor, and an inverter. A first terminal of the first resistor is electrically connected to the first terminal of the electronic device. A first terminal of the first capacitor is electrically connected to a second terminal of the first resistor, and a second terminal of the first capacitor is electrically connected to the second terminal of the electronic device. The inverter has an input terminal, an output terminal, a first power terminal, and a second power terminal. The input terminal of the inverter is electrically connected to the second terminal of the first resistor. The output terminal of the inverter is capable of generating the detection pulse. The first power terminal of the inverter is electrically connected to the first terminal of the electronic device. The second power terminal of the inverter is electrically connected to the second terminal of the electronic device.

Based on the above, the SCR is timely switched to the floating state by the switch unit. Thereby, the SCR is forced to switch back to the cutoff region, so as to prevent the SCR from being latched. In other words, compared to the related art, the invention is conducive to reduction of the layout area and costs because it is not necessary to cascade the SCRs for preventing the SCRs from being latched according to the invention.

Several exemplary embodiments accompanied with figures are described in detail below to further describe the invention in details.

### BRIEF DESCRIPTION OF THE DRAWINGS

The accompanying drawings are included to provide a further understanding of the disclosure, and are incorporated in and constitute a part of this specification. The drawings illustrate exemplary embodiments of the invention and, together with the description, serve to explain the principles of the invention.

FIG. 1 is a schematic diagram illustrating an electronic device according to an embodiment of the invention.

FIG. 2 is a timing waveform diagram according to an embodiment of the invention.

FIG. 3 is a schematic diagram illustrating a circuit of a control unit according to an embodiment of the invention.

FIG. 4 is a schematic cross-sectional diagram illustrating a silicon controlled rectifier (SCR) according to an embodiment of the invention.

### DETAILED DESCRIPTION OF DISCLOSED EXEMPLARY EMBODIMENTS

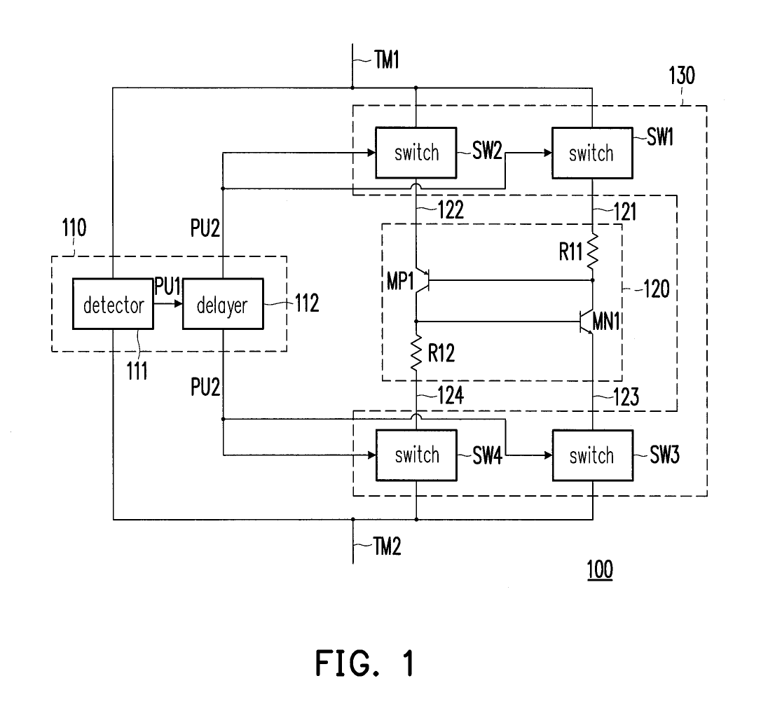

FIG. 1 is a schematic diagram illustrating an electronic device according to an embodiment of the invention. As shown in FIG. 1, an electronic device 100 has a first terminal TM1 and a second terminal TM2 and includes a control unit 110, a silicon controlled rectifier (SCR) 120, and a switch unit 130. For illustrative purposes, FIG. 1 merely shows the equivalent circuitry of the SCR 120, and the equivalent circuitry includes a PNP transistor MP1, an NPN transistor MN1, a resistor R11, and a resistor R12, as indicated in FIG. 1. The SCR 120 has a first anode terminal 121, a second anode terminal 122, a first cathode terminal 123, and a second cathode terminal 124.

As shown in FIG. 1, the control unit 110 includes a detector 111 and a delayer 112, and the switch unit 130 includes switches SW1˜SW4. The detector 111 is electrically connected to the first terminal TM1 and the second terminal TM2 of the electronic device 100. The delayer 112 is electrically connected to the detector 111 and the switches SW1˜SW4. The switch unit 130 provides a plurality of transmission paths via the switches SW1˜SW4. The switch SW1 is electrically connected between the first terminal TM1 of the electronic device 100 and the first anode terminal 121 of the SCR 120. The switch SW2 is electrically connected between the first terminal TM1 of the electronic device 100 and the second anode terminal 122 of the SCR 120. The switch SW3 is electrically connected between the second terminal TM2 of the electronic device 100 and the first cathode terminal 123 of the SCR 120. The switch SW4 is electrically connected between the second terminal TM2 of the electronic device 100 and the second cathode terminal 124 of the SCR 120.

Before describing the operation of the electronic device 100, the electronic device 100 is assumed to be applied in an integrated circuit (IC). The IC includes a bonding pad and a ground line, and the electronic device 100 is connected in series between the bonding pad and the ground line through the two terminals TM1 and TM2 of the electronic device 100. In general, the detector 111 detects a positive pulse signal that comes from the first terminal TM1 of the electronic device 100. When the positive pulse signal is detected, the detector 111 transmits a detection pulse PU1 to the delayer 112. The delayer 112 receives the detection pulse PU1. After the detection pulse PU1 is delayed for a predetermined time TP, the delayer 112 outputs the delayed detection pulse to serve as a reset pulse PU2.

Thereby, the switches SW1˜SW4 are turned off based on the reset pulse PU2, such that the four terminals 121˜124 of the SCR 120 maintain in a floating state. Namely, in general situations, the SCR 120 is connected in series between the two terminals TM1 and TM2 of the electronic device 100. However, when the first terminal TM1 of the electronic device 100 receives the positive pulse signal, i.e., at the time an ESD event occurs, the detector 111 of the control unit 110 generates the detection pulse PU1. After the detection pulse PU1 is delayed for a predetermined time TP, i.e., after the ESD event has occurred for a period of time, the delayer 112 of the control unit 110 outputs the reset pulse PU2 to the switch unit 130, such that the four terminals 121˜124 of the SCR 120 are floating.

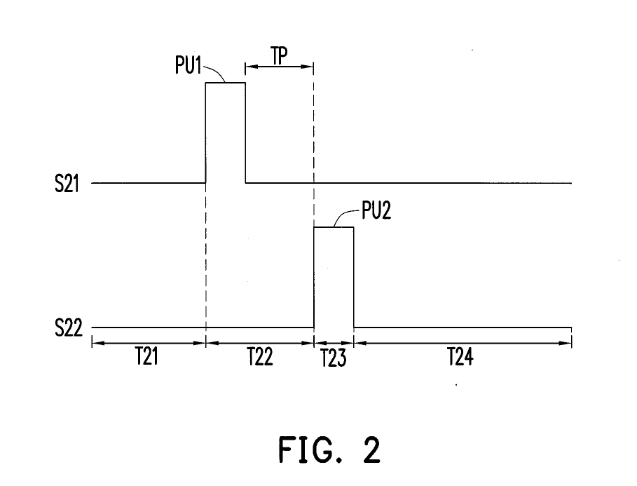

For instance, FIG. 2 is a timing waveform diagram according to an embodiment of the invention. S21 denotes the output signal of the detector 111, and S22 denotes the output signal of the delayer 112. As indicated in FIG. 2, in the time interval T21, the ESD event does not occur, and therefore the detector 111 is unable to detect the positive pulse signal from the first terminal TM1 of the electronic device 100. At this time, the detector 111 does not generate the detection pulse PU1, and thereby the switches SW1˜SW4 remain in a turn-on state. Thereby, the first anode terminal 121 and the second anode terminal 122 of the SCR 120 can be electrically connected to the first terminal TM1 of the electronic device 100 through the switches SW1 and SW2, and the first cathode terminal 123 and the second cathode terminal 124 of the SCR 120 can be electrically connected to the second terminal TM2 of the electronic device 100 through the switches SW3 and SW4. Namely, in the time interval T21, the SCR 120 is connected in series between the two terminals TM1 and TM2 of the electronic device 100.

As the ESD event occurs, the detector 111 detects the positive pulse signal that comes from the first terminal TM1 of the electronic device 100. At this time, the detector 111 generates the detection pulse PU1. After the detection pulse PU1 is delayed for the predetermined time TP, the delayer 112 outputs the delayed detection pulse PU1 to serve as the reset pulse PU2. It should be mentioned that the SCR 120 is still connected in series between the two terminals TM1 and TM2 of the electronic device 100 before the delayer 112 outputs the reset pulse PU2, i.e., within the time interval T22. Therefore, the SCR 120 is switched from the cutoff region to the negative resistance region in response to the positive pulse signal, and the SCR 120 further provides a conducting path to guide a great amount of electrostatic current to the ground line.

Besides, in the time interval T22, the SCR 120 may be latched in the negative resistance region. To avert said phenomenon, after the ESD event has occurred for a period of time, i.e., in the time interval T23, the delayer 112 outputs the reset pulse PU2 to the switch unit 130. At this time, the switches SW1˜SW4 in the switch unit 130 are turned off, such that the four terminals 121˜124 of the SCR 120 are floating. Thereby, the current flowing through the SCR 120 is gradually reduced to be equal to or less than a holding current, such that the SCR 120 is switched back to the cutoff region from the negative resistance region. When the delayer 112 stops outputting the reset pulse PU2, i.e., in the time interval T24, the SCR 120 is again connected in series between the two terminals TM1 and TM2 of the electronic device 100 and continues to be in the cutoff region.

In general, the switch unit 130 provides a plurality of transmission paths via the switches SW1˜SW4. In addition, under normal circumstances, the switch unit 130 is unable to receive the reset pulse PU2, and thus the switches SW1˜SW4 are turned on, i.e., the switch unit 130 turns on the transmission paths. As such, the SCR 120 is connected in series between the two terminals TM1 and TM2 of the electronic device 100. When the first terminal TM1 of the electronic device 100 receives the positive pulse signal, i.e., at the time an ESD event occurs, the electrostatic current is guided by the SCR 120 connected in series between the two terminals TM1 and TM2 of the electronic device 100.

After the ESD event has occurred for a period of time, the control unit 110 generates the reset pulse PU2. At this time, the switches SW1˜SW4 are not in the turn-on state, i.e., the switch unit 130 cuts off the transmission paths based on the reset pulse PU2. Thereby, the four terminals 121˜124 of the SCR 120 are floating, and thus the SCR 120 is forced to switch back to the cutoff region. In other words, it is not necessary to cascade the SCR 120 with other SCRs for fear of latching the SCR 120. According to this embodiment, the layout area and costs of the electronic device 100 can be reduced to a better extent.

In order for people having ordinary skill in the art to better understand the present embodiment, detailed circuit structure of the control unit 110 and the layout of the SCR 120 are further explained below.

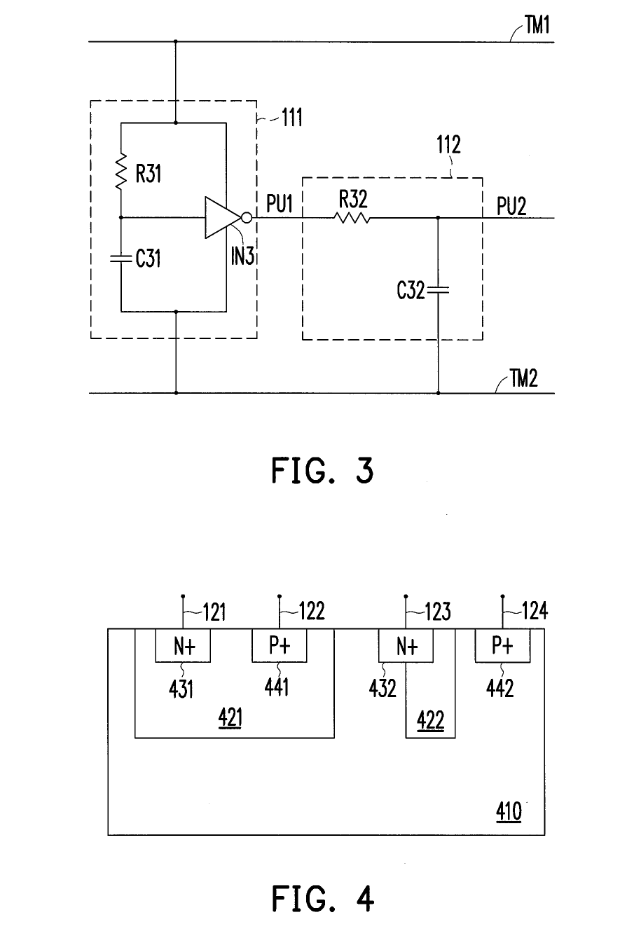

FIG. 3 is a schematic diagram illustrating a circuit of a control unit according to an embodiment of the invention. With reference to FIG. 3, the detector 111 includes a resistor R31, a capacitor C31, and an inverter IN3; the delayer 112 includes a resistor R32 and a capacitor C32. A first terminal of the resistor R31 is electrically connected to the first terminal TM1 of the electronic device 100. A first terminal of the capacitor C31 is electrically connected to a second terminal of the resistor R31, and a second terminal of the capacitor C31 is electrically connected to the second terminal TM2 of the electronic device 100.

The inverter IN3 has an input terminal, an output terminal, a first power terminal, and a second power terminal. The input terminal of the inverter IN3 is electrically connected to the second terminal of the resistor R31. The output terminal of the inverter IN3 is capable of generating the detection pulse PU1. The first power terminal of the inverter IN3 is electrically connected to the first terminal TM1 of the electronic device 100. The second power terminal of the inverter IN3 is electrically connected to the second terminal TM2 of the electronic device 100. In the delayer 112, a first terminal of the resistor R32 is electrically connected to the detector 111, and a second terminal of the resistor R32 is capable of outputting the reset pulse PU2. A first terminal of the capacitor C32 is electrically connected to the second terminal of the resistor R32, and a second terminal of the capacitor C32 is electrically connected to the second terminal TM2 of the electronic device 100.

As to operation, when the first terminal TM1 of the electronic device 100 receives a positive pulse signal, the inverter IN3 is started. Due to the high frequency of the positive pulse signal, a low-pass filter constituted by the resistor R31 and the capacitor C31 transmits a low-level signal to the inverter IN3. Thereby, the inverter IN3 can correspondingly generate a detection pulse PU1, i.e., a high-level signal. In addition, the delayer 112 can adjust a predetermined time based on the impedance of the resistor R32 and the capacitor C32. As such, the delayer 112 receives the detection pulse PU1; after the detection pulse PU1 is delayed for a predetermined time, the delayer 112 outputs the delayed detection pulse to serve as the reset pulse PU2.

FIG. 4 is a schematic cross-sectional diagram illustrating an SCR according to an embodiment of the invention. As shown in FIG. 4, the SCR 120 includes a p-type substrate 410, an n-type well 421, an n+-type doped region 431, a p+-type doped region 441, an n-type well 422, an n+-type doped region 432, and a p+-type doped region 442. The n-type well 421 and the n-type well 422 are disposed in the p-type substrate 410. The n+-type doped region 431 and the p+-type doped region 441 are disposed in the n-type well 421. The n+-type doped region 432 is partially disposed in the n-type well 422, and the p+-type doped region 442 is disposed in the p-type substrate 410. The n+-type doped region 431, the p+-type doped region 441, the n+-type doped region 432, and the p+-type doped region 442 are alternately arranged.

Please refer to both FIG. 1 and FIG. 4. In terms of the layout, the p+-type doped region 441, the n-type well 421, and the p-type substrate 410 together form a vertical PNP transistor MP1. The n-type well 421, the p-type substrate 410, and the n+-type doped region 432 together form a horizontal NPN transistor MN1. In addition, the resistor R11 is an equivalent resistor contributed by the n-type well 421, and the resistor R12 is an equivalent resistor contributed by the p-type substrate 410. As for electrical connection, the n+-type doped region 431 is electrically connected to the first anode terminal 121, the p+-type doped region 441 is electrically connected to the second anode terminal 122, the n+-type doped region 432 is electrically connected to the first cathode terminal 123, and the p+-type doped region 442 is electrically connected to the second cathode terminal 124.

In light of the foregoing, the four terminals of the SCR are timely switched to the floating state by the switch unit according to the embodiments of the invention. Thereby, the SCR is forced to switch back to the cutoff region, so as to prevent the SCR from being latched in the negative resistance region. In other words, it is not necessary to cascade the SCR with other SCRs for fear of latching the SCR. As such, the invention is conducive to the reduction of the layout area and costs of the electronic device.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. An electronic device having a first terminal and a second terminal and comprising:
a control unit detecting a positive pulse signal from the first terminal of the electronic device, when the positive pulse signal is detected by the control unit, the control unit generating a reset pulse after a predetermined time;
a silicon controlled rectifier having a first anode terminal, a second anode terminal, a first cathode terminal, and a second cathode terminal; and
a switch unit electrically connected to the first terminal and the second terminal of the electronic device and the silicon controlled rectifier, providing a plurality of transmission paths, when the switch unit receives the reset pulse, the switch unit cutting off the transmission paths, such that the first anode terminal, the second anode terminal, the first cathode terminal, and the second cathode terminal are floating.

2. The electronic device as recited in claim 1, wherein when the switch unit does not receive the reset pulse, the switch unit turns on the transmission paths, such that the first and second anode terminals are conducted to the first terminal of the electronic device, and that the first and second cathode terminals are conducted to the second terminal of the electronic device.

3. The electronic device as recited in claim 1, wherein the control unit comprises:
a detector detecting the positive pulse signal, when the positive pulse signal is detected, the detector generating a detection pulse; and
a delayer receiving the detection pulse, after the detection pulse is delayed for the predetermined time, the delayer outputting the delayed detection pulse to serve as the reset pulse.

4. The electronic device as recited in claim 3, wherein the detector comprises:
a first resistor having a first terminal electrically connected to the first terminal of the electronic device;
a first capacitor having a first terminal, electrically connected to a second terminal of the first resistor and a second terminal electrically connected to the second terminal of the electronic device; and
an inverter having an input terminal electrically connected to the second terminal of the first resistor, an output terminal for generating the detection pulse, a first power terminal electrically connected to the first terminal of the electronic device, and a second power terminal electrically connected to the second terminal of the electronic device.

5. The electronic device as recited in claim 3, wherein the delayer comprises:
a second resistor having a first terminal electrically connected to the detector, and a second terminal for outputting the reset pulse; and
a second capacitor having a first terminal electrically connected to the second terminal of the second resistor, and a second terminal electrically connected to the second terminal of the electronic device.

6. The electronic device as recited in claim 1, wherein the switch unit comprises:
a first switch electrically connected between the first terminal of the electronic device and the first anode terminal;
a second switch electrically connected between the first terminal of the electronic device and the second anode terminal;
a third switch electrically connected between the second terminal of the electronic device and the first cathode terminal; and
a fourth switch electrically connected between the second terminal of the electronic device and the second cathode terminal, wherein the first switch to the fourth switch are turned off based on the reset pulse.

7. The electronic device as recited in claim 1, wherein the silicon controlled rectifier comprises:
a p-type substrate;
a first n-type well disposed in the p-type substrate;
a first n+-type doped region disposed in the first n-type well and electrically connected to the first anode terminal;
a first p+-type doped region disposed in the first n-type well and electrically connected to the second anode terminal;
a second n-type well disposed in the p-type substrate;
a second n+-type doped region partially disposed in the second n-type well and electrically connected to the first cathode terminal; and
a second p+-type doped region disposed in the p-type substrate and electrically connected to the second cathode terminal.

8. The electronic device as recited in claim 7, wherein the first n+-type doped region, the first p+-type doped region, the second n+-type doped region, and the second p+-type doped region are alternately arranged.
